(19) United States
(12) Patent Application Publication
(10) Pub. No.: US 2025/0133798 A1
(43) Pub. Date: Apr. 24, 2025

(54) METHOD FOR FORMING A DEVICE COMPRISING GRAPHENE

(71) Applicant: GRAPHEAL, Grenoble (FR)

(72) Inventors: Vincent Bouchiat, Biviers (FR); Behnaz Djoharian, Biviers (FR); Riadh Othmen, Grenoble (FR)

(21) Appl. No.: 18/722,712

(22) PCT Filed: Dec. 20, 2022
(86) PCT No.: PCT/FR2022/052431

§ 371 Date: Jun. 21, 2024

(30) Foreign Application Priority Data
Dec. 22, 2021 (FR) FR2114282

(51) Int. Cl. H10D 62/80; C01B 32/194; H10D 62/17; H10D 62/57

(52) U.S. Cl. CPC H10D 62/882; C01B 32/194; H10D 62/221; H10D 62/57

(57) ABSTRACT

The invention relates to a method for forming a device (5) comprising graphene, the method comprising the following steps: —a step S1 of forming a graphene film (1) on a substrate (2); —a step S2 of depositing, on the graphene film (1), a functionalisation material (3) configured to modify physicochemical properties of the graphene film (1), the deposition of functionalisation material being configured to partially cover the graphene film (1); —a step S3 of gas-phase deposition of a polymer material (4) covering the graphene film (1) and the functionalisation material (3); and—a step S4 of removing the substrate (2) so that the polymer material (4) forms a support for the graphene film (1).

### FIELD OF THE INVENTION

The invention relates to the field of methods for forming devices comprising graphene. In particular, the invention relates to methods for forming devices including functionalised graphene, for example by placing the graphene on its rear face, in contact with objects enabling its functionalisation, in particular by doping.

### PRIOR ART

Graphene is a material composed of carbon atoms forming a crystal lattice with a thickness of one atom. By extension, and with a misuse of language, multilayer graphene is made up of from two to typically ten layers of single-layer graphene in a compact stack. Graphene is particularly advantageous for applications where semiconductors with high electron mobility are desired for detecting the movement of charges in their environment and their conversion into a variation in electrical conductivity of the graphene plane. The majority of applied electronic applications of graphene require a continuous layer of graphene of macroscopic size, comprising a single or few layers of carbon atoms, which layer is transferred onto a substrate of a material selected according to a particular application. Continuous graphene is generally synthesised using a chemical vapour deposition method (a technique also know to a person skilled in the art as CVD), in which the graphene crystallises on a scale of one or a few atomic layers on a base substrate with a catalytic function, such as a copper foil. The carbon of the graphene is sourced from a gas precursor, such as methane or other hydrocarbon.

It remains difficult to then remove the layer of graphene from the base substrate and to transfer it onto a target substrate, the surface of which is an electrical insulator, without structurally damaging or contaminating the two, high and low (or upper and lower), surfaces of the graphene layer, and/or degrading its electronic properties such as its conductivity or the mobility of the charge carriers.

It is also difficult to deposit, on one of the faces of the graphene, objects which allow it to be functionalised, in particular by doping or by proximity effect, without damaging or contaminating the upper graphene layer and/or degrading its electronic properties and, in particular, its sensitivity to the environment.

Graphene is functionalised by a functionalisation material if the material in contact or in proximity with the graphene modifies the physicochemical properties (electronic, optical, mechanical, chemical, etc.) of the graphene film, or indeed modifies the immediate environment of this film by a screening, filtering or remote influence affect.

There is therefore a need for a method for forming a device comprising functionalised graphene, which can preserve both the structural and electronic qualities of the graphene layer, expose its cleanest surface to the environment, namely that in contact with the catalytic substrate, while reducing the degree of contamination on its exposed face.

### DISCLOSURE OF THE INVENTION

An object of the invention is to propose a method for forming a device comprising functionalised graphene which overcomes the problems of the prior art.

The object is achieved in the context of the present invention through a method for forming a device comprising graphene, the method comprising the following steps:
a step of forming a graphene film on a substrate;
a step of depositing, on the graphene film, a functionalisation material configured to modify the physicochemical properties of the graphene film, the deposition of functionalisation material being configured to partially cover the graphene film, such that at least a portion of the graphene film is not covered by the functionalisation material;
a step of gas-phase deposition of a polymer material covering the graphene film and the functionalisation material, such that the polymer material is in contact with the at least one portion of the graphene film which is not covered by the functionalisation material; and
a step of removing the substrate so that the polymer material forms a support for the graphene film.

In this method, the various steps of deposition and removal do not degrade the integrity of the graphene film. Once the substrate is removed, the graphene has an exposed surface, this surface being originally in contact with the substrate and thus free from any contamination. The polymer material is in direct contact with the back face of the graphene film so as to functionalise it. The exposed—or free—surface of the graphene is clean and free from any contamination. The problem of functionalising graphene while preserving the quality of the graphene layer and the absence of surface contamination on one of the two faces is solved. The functionalisation performed directly enables an interaction with elements in proximity with the graphene film in a fluid deposited on the graphene.

Such a method is advantageously and optionally supplemented by the various following features, taken alone or in combination:
the functionalisation material is deposited on the graphene film in the form of elements having an average thickness in a direction perpendicular to the graphene film and an average lateral extent in a plane parallel to the graphene film,
the graphene film comprising, at the end of step of removing the substrate, a front face and a rear face opposite the front face,
the rear face being in contact with the functionalisation material and the polymer material,
the front face being free and having a roughness less than the average thickness of the elements the of functionalisation material, the roughness being determined relative to a flat surface, the roughness being equal to a standard deviation of a height of the front face in the perpendicular direction as a function of a position in a plane of the graphene film, the height of the front face being defined over areas in the plane, of a size greater than the average lateral extent;
the roughness relative to a reference plane is less than 10% of the average thickness, and preferably less than 5% of the average;
the polymer material comprises parylene;
the functionalisation material is deposited in the form of metal nanowires, and/or in the form of semiconductor nanowires or semiconductor quantum dots, and/or in the form of magnetic metal nanoparticles, and/or in the form of a lithographed metal thin-film, and/or in the form of a dielectric layer deposited by atomic layer deposition (ALD), and/or in the form of a layer of boron nitride deposited by chemical vapour deposition (CVD).

The invention also relates to a device comprising graphene, the device comprising a graphene film, partially covered with a functionalisation material configured to modify the electrical or magnetic properties of the graphene film, the device comprising a polymer material covering the graphene film and the functionalisation material, such that the polymer material is in contact with at least one portion of the graphene film which is not covered by the functionalisation material.

Such a device is advantageously and optionally supplemented by the following features:
the functionalisation material consists of elements having an average thickness in a direction perpendicular to the graphene film and an average lateral extent in a plane parallel to the graphene film,
the graphene film comprising a front face and a rear face opposite the front face,
the rear face being in contact with the functionalisation material and the polymer material,
the front face being free and having a roughness less than the average thickness of the elements of the functionalisation material, the roughness being determined relative to a flat surface, the roughness being equal to a standard deviation of a height of the front face in the perpendicular direction as a function of a position in a plane of the graphene film, the height of the front face being defined over areas in the plane, of a size greater than the average lateral extent;
the roughness relative to a reference plane is less than 10% of the average thickness, and preferably less than 5% of the average;
the polymer material comprises parylene;
the functionalisation material is present in the form of metal nanowires, and/or in the form of semiconductor nanowires or semiconductor quantum dots, and/or in the form of magnetic metal nanoparticles, and/or in the form of a lithographed metal thin-film, and/or in the form of a dielectric layer deposited by atomic layer deposition (ALD), and/or in the form of a layer of boron nitride deposited by chemical vapour deposition (CVD).

### DESCRIPTION OF THE FIGURES

Other features and advantages of the invention will emerge from the following description, which is given purely by way of illustration and not being limiting and which should be read with reference to the attached drawings, in which:

FIG. 1 is a schematic representation of the method for forming a device comprising graphene according to an embodiment of the invention;

FIGS. 2, 3A, 3B, 3C, 3D, 4 and 5 are schematic representations of steps of the method for forming a device according to embodiments of the invention;

FIG. 6 is a schematic representation of a device obtained by the method of formation according to an embodiment of the invention.

### DETAILED DESCRIPTION OF EMBODIMENTS OF THE INVENTION

### Method for Forming a Device Comprising Graphene

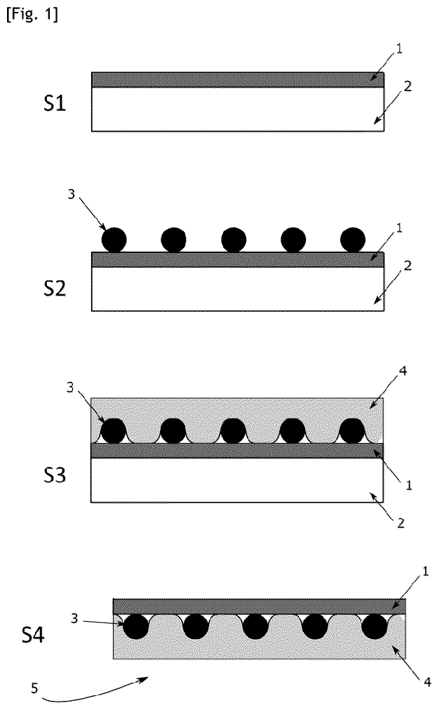

In conjunction with FIG. 1, a method is presented for forming a device comprising graphene. FIG. 1 shows sectional views of a graphene device during its manufacture.

In a first step S1, a graphene film 1 is formed, for example by chemical vapour deposition (CVD), on a substrate 2, which is for example made of copper.

Here, the substrate 2 plays the role of a growth substrate.

Other materials than copper are possible for forming the substrate. These materials include metals such as nickel, cobalt or ruthenium, or copper alloys such as alloys of copper and nickel, copper and cobalt, copper and ruthenium, or dielectric materials, such as zirconium dioxide, hafnium oxide, boron nitride and aluminium oxide.

Step S1 can, in particular, be implemented in a growth furnace.

The substrate 2 can be in the form of a foil, as illustrated in FIG. 1. The thickness of the foil is between 100 nm and 100 μm, but a thickness of order one centimetre or even ten centimetres is also possible.

The substrate 2 can also consist of a stack of layers some of which are reactive (copper or other) and others are refractory (alumina). A substrate in the multilayer form is necessary in the case where a very fine layer of copper (200 nm, for example) is used.

The graphene film 1 has, for example, a thickness of only one atom, or a larger thickness which can reach eight layers of atoms. This thickness can be adjusted as a function of the application and the desired electronic properties.

The formation of a graphene film on a substrate is described in document FR3033554A1.

The face of the graphene film 1 on the substrate 2 side, is called the front face, and the face of the graphene film 1 opposite the front face, is the rear face. The rear face is free—in other words not covered—at the end of step S1.

In a second step S2, a functionalisation material 3 configured to modify the physicochemical properties of the graphene film is deposited on the graphene film so as to partially cover the graphene film.

This deposition is configured such that at least one portion of the graphene film 1 is not covered by the functionalisation material 3.

The functionalisation can be obtained either directly by physical coupling through contact between the functionalising material and the graphene, or indirectly by remote influence (for example by an electric or magnetic field).

The functionalisation material 3 is deposited on the rear face of the graphene film and is, at the end of step S2, directly in contact with the graphene film.

The functionalisation material 3 only partially covers the rear face of the graphene film, such that at least one portion of the rear face of the graphene film 1 remains free—in other words such that at least one portion of the rear face is not covered by the functionalisation material. Preferably, at least 5% of the rear face of the graphene film is left free during the depositing of the functionalisation material. More preferably, at least 10% of the rear face of the graphene film is left free during the depositing of the functionalisation material.

The partial coverage of the graphene by the functionalisation material makes possible a later deposition of polymer on the functionalisation material and graphene, to preserve the adhesive properties between the graphene and the polymer.

The thickness of the functionalisation material deposited in step S2 is typically ten nanometres.

The thickness of the functionalisation material can typically be between 0.1 nm and 1 millimetre.

The types and forms of functionalisation materials that it is possible to deposit are described in more detail in the following text.

In order to protect the part from contamination of the rear face of the graphene film and from oxidation of the substrate, step S2 can be performed under a protective atmosphere.

For the same purpose, it is useful to rapidly perform step S2 once step S1 has been performed.

In a third step S3, a polymer material 4 is deposited in the gaseous phase, so as to cover the graphene film 1 and the functionalisation material 3. In particular, the polymer material 4 is in contact with the at least one portion of the graphene film 1 which is not covered by the functionalisation material 3.

The depositing of polymer material is carried out on the rear face side of the graphene film, in other words the polymer material is deposited on the portions of the rear face of the graphene film 1 that are not covered by the material, and on the functionalisation material deposited in step S2. A layer of polymer material is thus produced on the rear-face side of the graphene film.

The polymer material has an inner surface which is in contact with the rear face of the graphene and the functionalisation material, and an outer surface opposite the inner surface. The outer surface is free.

The deposition of polymer material can be configured to produce a layer thickness of polymer material much greater than the thickness of the functionalisation material as deposited at the end of step S2. In this way, the shape of the outer surface of the polymer material as deposited at the end of step S3 does not depend on step S2 and in particular on the irregular relief formed by the rear face of the graphene and the functionalisation material which partially covers it.

Step S3 can be configured so that the outer surface is flat and parallel to the graphene film.

The layer thickness of polymer material can be between 100 nanometres and 50 microns.

The polymer material is, for example, poly(para-xylylene), also referred to as n-xylylene or parylene.

Parylene is a biocompatible material.

Parylene also has the advantage of being able to be evaporated in the gas phase by producing a conformal layer on the covered surfaces, regardless of their horizontal or vertical orientation.

Furthermore, this method for forming the layer of parylene can be implemented at ambient temperature, in other words between 20 and 30° C. Consequently, it does not risk damaging the functionalisation material deposited on the graphene film. This makes it possible to encapsulate a functionalisation material that is sensitive to temperature, such as one or more biological objects, for example.

Parylene also has aromatic functions which interact strongly with graphene, so as to produce important adhesive properties between graphene and parylene.

Finally, parylene has the advantage of being able to be stretched by up to 200% before breaking, and is capable of remaining flexible over a relatively large temperature range. In an example, the polymer material comprises parylene C or parylene N. Parylene C and parylene N both have the advantage of being relatively elastic, whereas parylene N as a slightly lower Young's modulus, and thus a greater elasticity compared with parylene C.

In a fourth step S4, the substrate 2 is removed. A blank 5 of a device comprising a graphene film, a functionalisation material 3 and a layer of polymer 4 is thus obtained.

The front face of the graphene film is exposed or free—in other words not covered and in direct contact with the exterior air—and can be placed in contact with objects that it is desired to characterise.

The rear face of the graphene film is in contact with the functionalisation material which imparts particular functions to the graphene.

The graphene film and the functionalisation material are both held by the layer of polymer material.

The deposition of the polymer material traps the functionalisation material which functionalises the graphene while maintaining excellent adhesion, high flexibility of the graphene surface and large-scale electronic continuity of the graphene. In particular, the structure of the graphene film is not damaged during the method, so that the front face of the graphene film is clean and free of any contamination. Thus, surprisingly, even if the functionalisation material does not have adhesion properties with respect to graphene and/or the polymer material, the bond between the polymer material and the graphene in the regions left free by the deposition of the functionalisation material is sufficient to ensure good mechanical cohesion of the stack of graphene film, functionalisation material and polymer material.

The placing of the functionalisation material against the graphene is achieved with a better coupling, the functionalisation material being deposited on clean graphene with a good surface condition. The depositing of the functionalisation material minimises the mechanical stress on the graphene compared with other existing techniques.

A substrate 2 of copper can be removed by chemical attack using iron (III) chloride or sodium persulfate, or through delamination by oxidation of the copper in hot water, or even by delamination by electrochemical action and formation of a film of gas at the copper/graphene interface.

The surface of the graphene which appears due to the removal of the substrate is cleaned in order to remove any contamination, in particular contamination linked to etching of the copper.

Such a method has the advantage of being able to prepare large-scale devices using a spray on the graphene taken out of the growth furnace, in other words the graphene at the end of step S1.

Steps subsequent to step S4 can be implemented in order to finalise the device, in particular subsequent integration steps, such as the production of electric or electronic tracks in order to electrically connect the graphene and/or the functionalisation material to the connection terminals of the device.

### Roughness of the Graphene Film Front Face

The polymer material used in the method, and in particular parylene, enables a conformal deposition on the functionalisation material deposited on the graphene.

In this way, the polymer material enables encapsulation of the material and elements which compose this material, even if these elements have a high roughness, and this while maintaining the initial flatness of the graphene on the initial growth substrate.

The roughness of a surface is defined in the context of this invention relative to a perfectly flat reference plane.

The reference plane comprises two perpendicular directions X and Y—referred to as lateral directions—and defines a third direction Z perpendicular to the plane—referred to as the thickness direction.

In the perpendicular direction, a height (or altitude) z of the surface is defined relative to the reference plane.

This height z(x,y) is an average altitude relative to the reference plane of the surface over a zone centred on a a point with coordinates x, y of the reference plane, the zone having a lateral size DeltaX and a size DeltaY, in the lateral directions X and Y.

In order to quantify how the polymer material enables the encapsulation of the material and elements which compose this material while maintaining the flatness of the graphene, a roughness of the graphene film (for example of the front face) is defined over areas having a lateral size—or a lateral extent—greater than the average lateral extent of the elements which compose the functionalisation material deposited on the graphene.

The average lateral extent of the elements is the average size of the elements deposited on the graphene film measured in the lateral directions X and Y.

The average thickness of the elements is the average size of the elements deposited on the graphene film measured in the thickness direction Z.

Furthermore, the roughness is defined as the standard deviation of the distribution of heights z of the front face as a function of a position on the plane of the graphene film, this distribution being measured over areas which have a lateral extent greater than the lateral extent of the deposited objects. For example, the roughness can be defined over areas having a size two or three times greater than the average extent of the elements, in order to obtain the increase in roughness in this size range associated with deposition of the functionalisation material.

The method enables the flatness of the graphene to be preserved so that the front face of the graphene film has a roughness—compared with a surface without the presence of deposited elements—less than the average thickness of the deposited element.

Preferably, this roughness is less than 10% of the average thickness of the deposited elements, and more preferably less than 1% of the average thickness of the deposited elements.

For example, if the functionalisation material is composed of spherical beads, the roughness of the surface defined by the assembly of the rear face of the graphene film and the functionalisation material which covers it—i.e. the “rear face+functionalisation material” assembly—increases in value on the order of the diameter of the beads over a lateral sample greater than this diameter.

For a bead diameter of 4 micrometres, the roughness of this surface is of order 4 micrometres.

The roughness of the front face of the graphene obtained at the end of the method remains low and largely less than the roughness of the surface defined by the “rear face+functionalisation material” assembly.

It is of order 1% of the thickness of the objects, less than 5% of this thickness and in any case always less than 10% of this thickness.

FIG. 6 illustrates this effect in a device resulting from the method as previously described. The device comprises a graphene film 1, a functionalisation material in bead form 3 and a polymer material 4.

The graphene film has a free front face 1a and a rear face 1b in contact with the functionalisation material 3 and the polymer material 4.

The roughness is linked to the variations in height measured in the thickness direction Z, over the transverse zones, the size of which is measured here in the lateral direction X.

The bead 3 has a diameter T which corresponds to its thickness and its lateral size.

T is the average size in all directions of the elements composing the functionalisation material.

The deposition of polymer material being conformal, the thickness of the layer of polymer material has a variation in thickness e1 at the bead 3, this variation being equal to or of the same order as the average size T.

The roughness of the front face 1a is linked to the variations in height e2 measured in the thickness direction Z, over the transverse zones for which the size is measured here in the lateral direction X.

This variation e2 is at least ten times less than the variation in height e1, so that the flatness of the graphene is maintained throughout the method.

By way of comparison, in a method consisting of depositing the functionalising material on a substrate so as to partially cover the substrate, then subsequently covering the substrate and the functionalising material with a graphene film (for example by liquid-phase deposition), the roughness of the graphene film—for example the roughness of the face free of the film—is of the same order as the thickness of the objects which compose the functionalising material, because the deposition of the graphene is conformal.

The preservation of the flatness of the graphene makes the method very useful in the case where the functionalisation material is composed of objects having a “thickness/lateral size” aspect ratio greater than or equal to 1. This is the case, in particular, when these objects are spherical nanoparticles, nanocrystals or nanotubes.

The preservation of the flatness of the graphene makes it possible to avoid mechanical stresses which would apply in the graphene film, and to avoid any tearing.

The method enables both a direct contact of the graphene with the functionalising objects having a “thickness/lateral size” aspect ratio greater than or equal to 1, without the risk of tearing.

### Functionalisation Material

It is possible to deposit various types and various forms of functionalisation materials on the rear face of the graphene film.

In a first embodiment, the functionalisation material is deposited in the form of metal nanowires.

These metal nanowires can, in particular, be deposited by drop casting (term designating a method for forming a fine solid layer by depositing a solution on a flat surface then evaporating the solvent from the solution) or by spin coating (term known to a person skilled in the art and designating a method for coating a surface by centrifugation of a viscous liquid) on the graphene film.

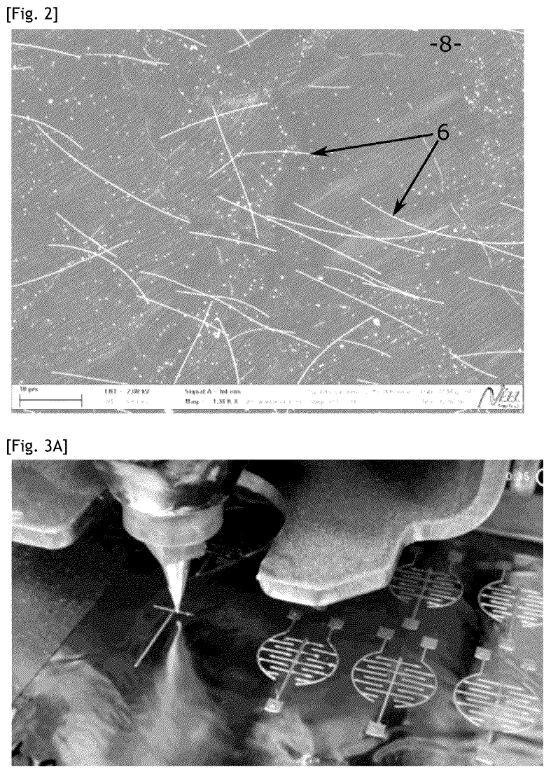

FIG. 2 is a scanning microscopy image of a device comprising a layer of polymer, in this case parylene, and a graphene film. Between the layer of parylene and the graphene, silver nanowires 6 have been deposited by spin coating. The graphene layer is so fine that it does not appear in the image, such that the grey background 8 of figure corresponds to the polymer layer which holds the silver nanowires 6 and the graphene layer.

The silver nanowires were deposited during step S2 by drop casting on the graphene film.

The device was produced according to the method described above, with a copper substrate. The copper substrate was removed during step S4.

The presence of silver nanowires can reinforce the conduction of the graphene layer.

Such a device can be used, in particular, to produce electrodes and conductive thin films.

In a second embodiment, the functionalisation material is deposited in the form of semiconductor or metal nanowires or semiconductor quantum dots.

These metal nanowires can be deposited, in particular, by drop casting, spin coating, simple dipping or spraying on to the graphene film.

The presence of semiconductor nanowires or semiconductor quantum dots enables transducing of light into electric charge. A luminous flux incident on the nanowire or quantum dot can thus be converted into a flow of electric charges. These semiconductor nanowires or semiconductor quantum dots are well protected from the effect of the environment, since they are encapsulated by the graphene and parylene.

Such a device can be used, in particular, to produce photosensors, flexible light sensors or oxygen saturation detectors (commonly referred to as “SpO2” sensors).

In a third embodiment, the functionalisation material is deposited in the form of magnetic metal nanoparticles.

These magnetic metal nanoparticles can be deposited, in particular, by drop casting or spin coating on the graphene film.

The presence of magnetic metal nanoparticles enables the generation of a local magnetic field.

Such a device can be used, in particular, to produce magnetic sensors or biosensors.

By remote effects through the graphene—the graphene does not screen certain interactions, in particular electromagnetic interactions—such a device enables the object that it is desired to characterise, and that is placed on the front face of the graphene, to interact with the functionalisation medium that is the metal nanoparticles. This enables a selectivity of the sensor by remote interaction with the object.

Alternatively, a discontinuous ferromagnetic layer can replace the magnetic nanoparticles.

It should be noted that the interaction through the graphene can be measured by the graphene itself. For example, if the functionalisation material comprises a nano-magnet inserted between the graphene and the polymer material, a magnetic particle that is present close to the front face of the graphene will be attracted towards the front face and it is possible to detect this attraction in the graphene.

In a fourth embodiment, the functionalisation material is deposited in the form of a lithographed metal thin-film.

This lithographed metal thin-film can be deposited, in particular, by physical vapour deposition (term also known by the acronym PVD) for example by evaporation under vacuum—or even by inkjet deposition of ink, on the graphene film.

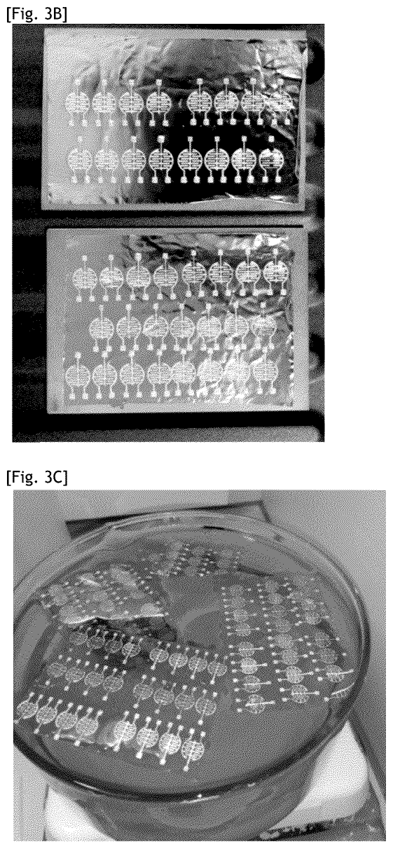

FIGS. 3A, 3B, 3C and 3D are images of various steps of an embodiment of the fourth mode.

FIG. 3A shows the inkjet deposition of silver ink, which corresponds to step S2 of the method in the case of this fourth mode example. The deposition takes place on the graphene covering the copper substrate. The graphene being very fine, it is the copper which is visible due to transparency in FIG. 3A.

FIG. 3B shows the graphene covering the copper substrate, once the inkjet lithography is completed.

FIG. 3C shows step S4 of removing the copper substrate.

FIG. 3D shows the device comprising graphene at the end of the step of removing the copper substrate.

The presence of the lithographed metal thin-film makes it possible to implement underlying connectivity on graphene, such as a set of electrical or electronic circuits for example, for connection between the graphene layer and the remainder of a larger device.

Such a device can be used, in particular, to produce flexible printed circuits or embedded sensors, for example sensors placed on the skin of plasmonic-effect photosensors.

In a fifth embodiment, the functionalisation material is deposited in the form of a dielectric layer by Atomic Layer Deposition (term also known by the acronym ALD). It should be noted that the atomic layer deposition technique requires an increase in temperature to 200° C., which reduces the types of functionalising material that can be deposited without being damaged.

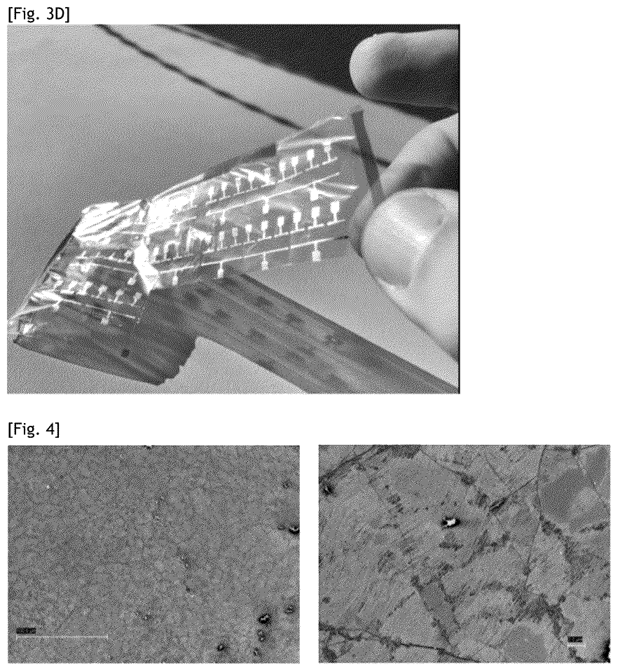

FIG. 4 is a scanning microscopy image of a device comprising a layer of polymer, in this case parylene, and a graphene film between which a dielectric layer of alumina (Al₂O₃) is deposited.

The dielectric layer of alumina has a thickness of approximately 10 nanometres.

The graphene layer is fine so that it does not appear in the image, the alumina layer appearing by transparency.

The device was produced according to the method described above, with a copper substrate. The copper substrate was removed during step S4.

The presence of the dielectric layer makes it possible to carry out a preparation of the surface of the graphene.

Such a device can be used, in particular, to produce improvements in electronic performance of the graphene.

In a sixth embodiment, the functionalisation material is deposited in the form of a boron nitride layer. This dielectric layer can be deposited by CVD.

The presence of the boron nitride layer enables an electrically insulating layer to be placed in contact with the graphene.

Such a device can be used, in particular, to produce improvements in electronic performance of the graphene.

In a seventh embodiment, the functionalisation material is deposited in the form of atoms, ions or molecules. By way of example in the case of molecules, viologen can be deposited. These materials can be deposited by spin coating.

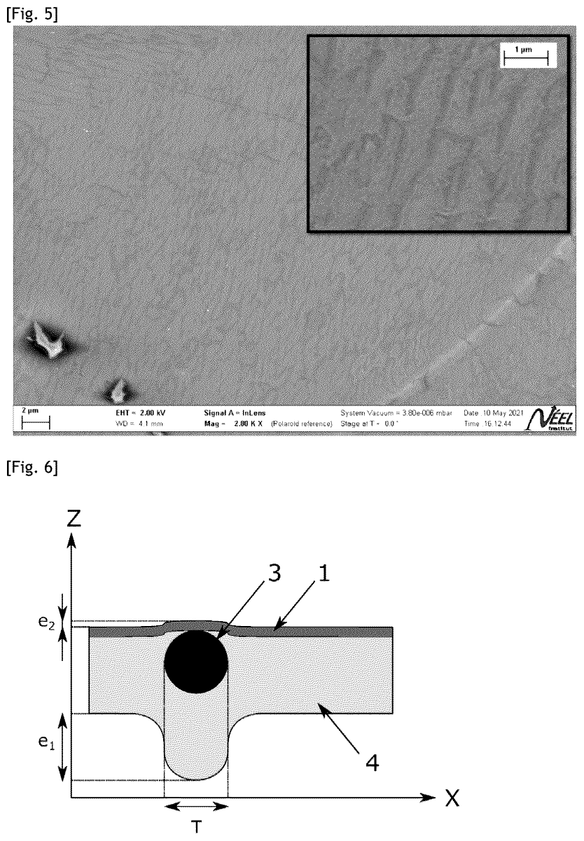

FIG. 5 comprises two scanning microscopy images of a device comprising a polymer layer, in this case parylene, and a graphene film between which molecules of viologen are deposited.

The device was produced according to the method described above, with a copper substrate. The copper substrate was removed during step S4.

The presence of viologen enables n-doping of the graphene layer.

Such a device can be used, in particular, to produce any electrical device using n-doping regions based on the spatial organisation between, on the one hand, graphene zones not doped with viologen and, on the other hand, graphene zones doped with viologen.

In an eighth embodiment, the functionalisation material is deposited by vapour deposition. The functionalisation material can be deposited by condensation of a vapour or a mist on the graphene film. The vapour contains a volatile element, for example pumped from a liquid phase via a vacuum chamber. This vapour then recondenses in contact with the graphene film. Very small quantities of this vapour can be sent onto the graphene film using a pulsed valve.

The vapour can contain a plurality of volatile elements.

For example, the volatile element can be an acid or a base, an oxidising element or a reducing agent, or even a volatile organic compound.

This volatile element can play the role, once deposited, of a dopant or of a functionalising species of the graphene.

At the end of the manufacturing method, the volatile element is located between the graphene and the polymer. In particular, it is protected by the graphene layer from oxidation by an element such as oxygen, which is located on the other side of the graphene. This protection does not prevent the volatile element from interacting through the graphene with elements smaller than oxygen, such as hydrogen for example, these elements also being located on the other side of the graphene.

The method described above makes it possible to create devices comprising graphene, the device comprising a graphene film, partially covered with a functionalisation material configured to modify the physicochemical properties of the graphene film, the device comprising a polymer material covering the graphene film and the functionalisation material, such that the polymer material is in contact with at least one portion of the graphene film which is not covered by the functionalisation material.

The invention therefore also relates to such devices, the surface condition of which on the front face of the graphene film cannot be obtained by existing techniques of the prior art.

In particular, the invention relates to such devices in which the polymer material is parylene.

The method also enables the production of field-effect transistors, which are flexible and the channel of which is made of graphene. The sensitive zone of such a transistor can correspond to an interruption in a ribbon of functionalisation material separating the graphene and the polymer.

1. A method for forming a device comprising graphene, the method comprising the following steps:
a step S1 of forming a graphene film on a substrate;
a step S2 of depositing, on the graphene film, a functionalisation material configured to modify the physicochemical properties of the graphene film, the deposition of the functionalisation material being configured to partially cover the graphene film such that at least a portion of the graphene film is not covered by the functionalisation material;
a step S3 of gas-phase deposition of a polymer material covering the graphene film and the functionalisation material, such that the polymer material is in contact with the at least one portion of the graphene film, the at least one portion of the graphene film being not covered by the functionalisation material; and
a step S4 of removing the substrate so that the polymer material forms a support for the graphene film.

2. The method according to claim 1, wherein the functionalisation material consists in elements having an average thickness in a direction perpendicular to the graphene film and an average lateral extent in a plane parallel to the graphene film,
the graphene film comprising at the end of step S4, a front face and a rear face opposite the front face,
the rear face being in contact with the functionalisation material and the polymer material,
the front face being free and having a roughness inferior to the average thickness of the elements of the functionalisation material,
the roughness being determined relative to the plane parallel to the graphene film, the roughness being equal to a standard deviation of a height separating the plane parallel to the graphene film and the front face in the perpendicular direction as a function of a position in the plane parallel to the graphene film, the position being defined over areas in the plane of a size greater than the average lateral extent.

3. The method according to claim 2, wherein the roughness is less than 10% of the average thickness, and preferably less than 5% of the average thickness.

4. The method according to claim 1, wherein the polymer material comprises parylene.

5. The method according to claim 1, wherein the functionalisation material is deposited in at least one of the following forms: metal nanowires, semiconductor nanowires, semiconductor quantum dots, magnetic metal nanoparticles, a lithographed metal thin-film, a dielectric layer deposited by atomic layer deposition (ALD) and a layer of boron nitride deposited by chemical vapour deposition (CVD).

6. A device comprising graphene, the device comprising a graphene film, partially covered with a functionalisation material configured to modify the electrical or magnetic properties of the graphene film, the device comprising a polymer material covering the graphene film and the functionalisation material such that the polymer material is in contact with at least one portion of the graphene film, the at least one portion of the graphene film being not covered by the functionalisation material.

7. The device according to claim 6 wherein the functionalisation material consists of elements having an average thickness in a direction perpendicular to the graphene film and an average lateral extent in a plane parallel to the graphene film,
the graphene film comprising a front face and a rear face opposite the front face,
the rear face being in contact with the functionalisation material and the polymer material,
the front face being free and having a roughness less than the average thickness of the elements of the functionalisation material,
the roughness being determined relative to the plane parallel to the graphene film, the roughness being equal to a standard deviation of a height separating the plane parallel to the graphene film and the front face in the perpendicular direction as a function of a position in the plane parallel to the graphene film, the position being defined over areas in the plane of a size greater than the average lateral extent.

8. The device according to claim 6 wherein the roughness is less than 10% of the average thickness, and preferably less than 5% of the average thickness.

9. The device according to claim 6, wherein the polymer material comprises parylene.

10. The device according to claim 6, wherein the functionalisation material (3) is deposited in at least one of the following forms: metal nanowires, semiconductor nanowires, semiconductor quantum dots, magnetic metal nanoparticles, a lithographed metal thin-film, a dielectric layer deposited by atomic layer deposition (ALD) and a layer of boron nitride deposited by chemical vapour deposition (CVD).
